(19) United States
(12) Patent Application Publication
(10) Pub. No.: US 2020/0362200 A1
(43) Pub. Date: Nov. 19, 2020

(54) SEMICONDUCTOR PROCESSING COMPOSITION AND PROCESSING METHOD

(71) Applicant: JSR CORPORATION, Tokyo (JP)

(72) Inventors: Saki Ando, Tokyo (JP); Masashi Okamoto, Tokyo (JP); Tatsuya Yamanaka, Tokyo (JP); Masayuki Usuda, Tokyo (JP)

(73) Assignee: JSR CORPORATION, Tokyo (JP)

(21) Appl. No.: 16/872,338

(22) Filed: May 11, 2020

(30) Foreign Application Priority Data
May 13, 2019 (JP) 2019-090602

(51) Int. Cl. C09G 1/18; H01L 21/02; H01L 21/321

(52) U.S. Cl. CPC C09G 1/18; H01L 21/3212; H01L 21/02074

(57) ABSTRACT

A semiconductor processing composition that can reduce an etching rate of cobalt and minimize corrosion of a cobalt site due to a surface treatment when used for a treatment such as semiconductor cleaning and chemical mechanical polishing. A semiconductor processing composition according to one aspect of the disclosure is a semiconductor processing composition which includes glutamic acid, and at least one selected from the group consisting of histidine, cysteine and glycine, and used for processing an exposed cobalt surface. A semiconductor processing composition according to one aspect of the disclosure is a semiconductor processing composition which includes a compound having a structure in which glutamic acid, and at least one selected from the group consisting of histidine, cysteine and glycine are peptide-bonded and is used for processing an exposed cobalt surface.

### CROSS-REFERENCE TO RELATED APPLICATION

This application claims the priority benefit of Japan application serial no. 2019-090602, filed on May 13, 2019. The entirety of the above-mentioned patent application is hereby incorporated by reference herein and made a part of this specification.

### BACKGROUND

### Technical Field

The disclosure relates to a semiconductor processing composition and a processing method using the same.

### Description of Related Art

A metal wiring made of copper, tungsten, cobalt or the like is exposed on a surface to be treated in a semiconductor producing process such as a surface to be polished in chemical mechanical polishing (CMP) and a surface to be cleaned from which it is necessary to remove contaminants such as polishing debris and organic residues after a producing process such as CMP. In recent years, cobalt has started to be used as a wiring material, and accordingly, processing agents such as a CMP slurry and a cleaning agent for minimizing corrosion of a cobalt site exposed on the surface have begun to be studied. For example, in Patent Document 1, in order to clean a surface with exposed cobalt to be treated, a cleaning agent containing a specific water-soluble polymer is disclosed.

### PATENT DOCUMENTS

[Patent Document 1] WO2017/108748

### SUMMARY

Compared to wiring materials such as copper and tungsten, a cobalt site tends to easily corrode due to a surface treatment such as surface cleaning.

Some aspects according to the disclosure provide semiconductor processing compositions that can reduce an etching rate of cobalt and minimize corrosion of a cobalt site due to a surface treatment.

One aspect of a semiconductor processing composition according to the disclosure is a semiconductor processing composition for processing an exposed cobalt surface, including glutamic acid, and at least one selected from the group consisting of histidine, cysteine, and glycine.

In one aspect of the semiconductor processing composition, when the content of the glutamic acid is Ma1 [mass %], and the content of the at least one selected from the group consisting of histidine, cysteine, and glycine is Ma2 [mass %], Ma1/Ma2 may be 0.1 to 20.

One aspect of a semiconductor processing composition according to the disclosure is a semiconductor processing composition for processing an exposed cobalt surface including a compound having a structure in which glutamic acid, and at least one selected from the group consisting of histidine, cysteine and glycine are peptide-bonded.

Any of the aspects of the semiconductor processing composition may further include at least one selected from the group consisting of ammonia and an ammonium salt.

In any of the aspects of the semiconductor processing composition, the pH may be 1 to 6.

Any of the aspects of the semiconductor processing composition may further contain an oxidant.

One aspect of a processing method according to the disclosure includes a process of processing a surface of a workpiece having an exposed cobalt surface using the semiconductor processing composition according to any one of the aspects in a condition in which the temperature of the composition is 20 to 40° C.

In one aspect of the processing method, in the process, the composition and the exposed cobalt surface may be brought into contact with each other for 30 to 60 seconds.

According to the semiconductor processing composition according to the disclosure, when the composition is used for a surface to be treated in the semiconductor producing process, it is possible to reduce an etching rate of cobalt and minimize corrosion of the cobalt site.

### DESCRIPTION OF THE EMBODIMENTS

Preferable embodiments of the disclosure will be described below in detail. Here, the disclosure is not limited to the following embodiments, and includes various modified examples implemented in ranges without changing the spirit of the disclosure.

In this specification, a numerical range described as “A to B” is interpreted as a range including the numerical value A as a lower limit value and the numerical value B as an upper limit value.

### 1. Semiconductor Processing Composition

Preferable embodiments of the disclosure can be broadly classified into the following two embodiments: a first embodiment and a second embodiment.

A semiconductor processing composition according to the first embodiment of the disclosure is a semiconductor processing composition for processing an exposed cobalt surface, and contains glutamic acid, and at least one selected from the group consisting of histidine, cysteine and glycine.

A semiconductor processing composition according to the second embodiment of the disclosure is a semiconductor processing composition for processing an exposed cobalt surface, and includes a compound having a structure in which glutamic acid, and at least one selected from the group consisting of histidine, cysteine and glycine are peptide-bonded.

Here, the semiconductor processing compositions according to the first and second embodiments can be used as a processing agent such as a CMP slurry for a chemical mechanical polishing, a cleaning agent for removing particles and metal impurities present on the surface of a workpiece after CMP is completed, a resist release agent for releasing a resist from a semiconductor substrate treated using the resist, or an etching agent for removing surface contaminants by shallow etching a surface of a metal wiring or the like.

The semiconductor processing composition according to the first and second embodiments may be prepared by adding a liquid medium to a concentrated type semiconductor processing composition and performing dilution, or may be an undiluted type semiconductor processing composition. The above concentrated type semiconductor processing composition is generally present in a form in which components are concentrated. Therefore, each user prepares a processing agent by diluting the above concentrated type semiconductor processing composition in a liquid medium or uses an undiluted type semiconductor processing composition as a processing agent without change, and can use the processing agent as a CMP slurry for chemical mechanical polishing, a cleaning agent for cleaning a semiconductor surface, a resist release agent, or an etching agent. Hereinafter, respective components included in the semiconductor processing compositions according to the first and second embodiments will be described in detail.

### 1.1. First Embodiment

The semiconductor processing composition according to the first embodiment of the disclosure is a semiconductor processing composition for processing an exposed cobalt surface, and contains glutamic acid, and at least one selected from the group consisting of histidine, cysteine and glycine.

1.1.1. Glutamic Acid

The semiconductor processing composition according to the first embodiment contains glutamic acid. Glutamic acid has an effect of minimizing corrosion of a cobalt site on a surface to be treated. A mechanism by which glutamic acid minimizes corrosion of a cobalt site is not clear, but is speculated to be as follows.

An exposed cobalt surface to be treated tends to easily react with oxygen and water in the atmosphere. This is because hydroxy groups are present on the exposed cobalt surface. Therefore, glutamic acid having two carboxy groups and one amino group can be strongly adsorbed to the exposed cobalt surface. As a result, it is thought that, glutamic acid can more effectively protect the exposed cobalt surface than amino acids having other structures, and can reduce an etching rate of cobalt, and exhibit an effect of minimizing corrosion of the cobalt site.

When the semiconductor processing composition of the first embodiment is used as a processing agent such as a cleaning agent or a CMP slurry, the lower limit value of the content (Ma1 [mass %]) of the glutamic acid is preferably 0.001 mass %, more preferably 0.005 mass %, and particularly preferably 0.01 mass % with respect to the total mass of the processing agent. The upper limit value of the content (Ma1 [mass %]) of the glutamic acid is preferably 1.5 mass %, more preferably 1 mass %, and particularly preferably 0.5 mass %. If the content of the glutamic acid in the processing agent is within the above range, when used for a treatment such as cleaning and polishing, corrosion of the cobalt site can be effectively minimized.

1.1.2. Histidine, Cysteine and Glycine

The semiconductor processing composition according to the first embodiment contains at least one selected from the group consisting of histidine, cysteine, and glycine. When at least one selected from the group consisting of histidine, cysteine, and glycine and glutamic acid are used in combination, it is possible to more effectively minimize corrosion of the cobalt site.

Generally, histidine, cysteine and glycine are amino acids that easily form a water-insoluble complex with metal ions. As described above, it is thought that, when glutamic acid is adsorbed to an exposed surface of a cobalt wiring, a protective film for minimizing corrosion is formed. However, it is speculated that, when at least one selected from the group consisting of histidine, cysteine, and glycine is used in combination, a protective film of a water-insoluble complex derived from these amino acids is additionally formed on the exposed surface of the cobalt wiring. As a result, it is thought that it is possible to exhibit a more effective corrosion minimizing effect, which could not be realized with glutamic acid alone.

Among these amino acids, preferably, histidine and cysteine are used in combination. When histidine and cysteine are used in combination, a favorable protective film of a water-insoluble complex is formed on the exposed surface of the cobalt wiring, and it is possible to minimize more effectively corrosion of the cobalt site.

When the semiconductor processing composition of the first embodiment is used as a processing agent such as a cleaning agent or a CMP slurry, the lower limit value of the content of each of histidine, cysteine and glycine is preferably 0.001 mass %, more preferably 0.005 mass %, and particularly preferably 0.01 mass % with respect to the total mass of the processing agent. The upper limit value of the content of each of histidine, cysteine and glycine is preferably 1 mass %, more preferably 0.1 mass %, and particularly preferably 0.05 mass %. If the content of each of histidine, cysteine and glycine in the processing agent is within the above range, when used for a treatment such as cleaning and polishing, it is possible to minimize more effectively corrosion of the cobalt site.

When the semiconductor processing composition of the first embodiment is used as a processing agent such as a cleaning agent or a CMP slurry, the lower limit value of the content (Ma2 [mass %]) of at least one selected from the group consisting of histidine, cysteine, and glycine is preferably 0.001 mass %, more preferably 0.005 mass %, and particularly preferably 0.01 mass % with respect to the total mass of the processing agent. The upper limit value of the content (Ma2 [mass %]) of at least one selected from the group consisting of histidine, cysteine, and glycine is preferably 1 mass %, more preferably 0.1 mass %, and particularly preferably 0.05 mass %. If the content of each of histidine, cysteine and glycine in the processing agent is within the above range, when used for a treatment such as cleaning and polishing, it is possible to minimize more effectively corrosion of the cobalt site.

1.1.3. Ammonia and Ammonium Salt

The semiconductor processing composition according to the first embodiment may contain at least one selected from the group consisting of ammonia and an ammonium salt. It is speculated that, since ammonia and an ammonium salt can remove in advance components that may inhibit formation of a protective film from the exposed cobalt surface, they assist with or promote formation of a protective film using glutamic acid, and at least one selected from the group consisting of histidine, cysteine and glycine. As a result, it is thought that, when at least one selected from the group consisting of ammonia and an ammonium salt is used in combination, it is possible to effectively minimize corrosion of the cobalt site.

When the semiconductor processing composition of the first embodiment is used as a processing agent such as a cleaning agent or a CMP slurry, the lower limit value of the content (Ma3 [mass %]) of at least one selected from the group consisting of ammonia and an ammonium salt is preferably 0.0001 mass %, more preferably 0.0005 mass %, and particularly preferably 0.001 mass % with respect to the total mass of the processing agent. The upper limit value of the content of at least one selected from the group consisting of ammonia and an ammonium salt is preferably 0.5 mass %, more preferably 0.3 mass %, and particularly preferably 0.2 mass %.

1.1.4. Liquid Medium

The semiconductor processing composition according to the first embodiment contains a liquid medium. The type of the liquid medium can be appropriately selected depending on the purpose of use of the processing agent such as polishing, cleaning, etching, and resist releasing. When the semiconductor processing composition according to the first embodiment is used as a CMP slurry or a cleaning agent, the liquid medium is preferably an aqueous medium containing water as a main component. Examples of such an aqueous medium include water, a medium in which water and an alcohol are mixed, and a medium in which water and an organic solvent having compatibility with water are mixed. Among these aqueous mediums, water, and a medium in which water and an alcohol are mixed are preferably used, and water is more preferably used. The liquid medium simply needs to be a mixture for the remainder of materials constituting the semiconductor processing composition, and the content of the liquid medium is not particularly limited.

1.1.5. Other Components

The semiconductor processing composition according to the first embodiment may contain, as necessary, components other than the above components. Examples of other components include an oxidant, an abrasive, a surfactant, and a pH adjusting agent. These components may be used alone or two or more thereof may be used in combination.

1.1.5.1. Oxidant

Examples of oxidants include organic peroxides such as hydrogen peroxide, peracetic acid, perbenzoic acid, and tert-butyl hydroperoxide; permanganate compounds such as potassium permanganate; bichromate compounds such as potassium dichromate; halogen oxides such as potassium iodate; nitric acid compounds such as iron nitrate; perhalogen oxides such as perchloric acid; persulfates such as ammonium persulfate; and heteropoly acids. These oxidants may be used alone or two or more thereof may be used in combination.

When the semiconductor processing composition according to the first embodiment is processed as a processing agent such as a cleaning agent or a CMP slurry, the lower limit value of the content of the oxidant is preferably 0.01 mass %, more preferably 0.05 mass %, and particularly preferably 0.1 mass %. The upper limit value of the content of the oxidant is preferably 5 mass %, more preferably 3 mass %, and particularly preferably 1 mass %.

1.1.5.2. Abrasive

When the semiconductor processing composition according to the first embodiment is used as a CMP slurry, it preferably contains an abrasive. A known material can be used as the abrasive, and inorganic oxide particles and organic particles are preferable.

Examples of inorganic oxide particles include inorganic oxide particles of silica, ceria, alumina, zirconia, and titania. Among these, in order to reduce the occurrence of scratches on the cobalt wiring or the like, silica is preferable, and colloidal silica is more preferable.

When the semiconductor processing composition according to the first embodiment is used as a CMP slurry, the content of the abrasive is preferably 0.2 to 10 mass %, and more preferably 0.3 to 5 mass % with respect to the total mass of the CMP slurry.

1.1.5.3. Surfactant

Examples of surfactants include an anionic surfactant and a nonionic surfactant. When such a surfactant is used, contaminants remaining on the surface to be treated including the cobalt site may be dispersed in the processing agent and removed.

Examples of anionic surfactants include alkylbenzene sulfonic acids such as dodecylbenzene sulfonic acid; alkylnaphthalene sulfonic acids; alkyl sulfates such as lauryl sulfate; sulfuric esters of polyoxyethylene alkyl ethers such as polyoxyethylene lauryl sulfate; naphthalenesulfonic acid condensates; and lignin sulfonic acid. These anionic surfactants may be used in the form of a salt.

Examples of nonionic surfactants include polyoxyethylene alkyl ethers such as polyoxyethylene lauryl ether, polyoxyethylene cetyl ether, polyoxyethylene stearyl ether, and polyoxyethylene oleyl ether; polyoxyethylene aryl ethers such as polyoxyethylene octyl phenyl ether, and polyoxyethylene nonyl phenyl ether; sorbitan fatty acid esters such as sorbitan monolaurate, sorbitan monopalmitate, and sorbitan monostearate; and polyoxyethylene sorbitan fatty acid esters such as polyoxyethylene sorbitan monolaurate, polyoxyethylene sorbitan monopalmitate, and polyoxyethylene sorbitan monostearate.

These surfactants may be used alone or two or more thereof may be used in combination.

When the semiconductor processing composition according to the first embodiment is used as a processing agent such as a cleaning agent or a CMP slurry, the content of the surfactant is preferably 0.001 to 1 mass %, and more preferably 0.001 to 0.1 mass % with respect to the total mass of the processing agent.

1.1.5.4. pH Adjusting Agent

Examples of pH adjusting agents include inorganic acids and salts thereof; natural amino acids such as alanine, arginine, and asparagine; organic acids such as citric acid, maleic acid, malic acid, tartaric acid, oxalic acid, malonic acid, and succinic acid; and alkali metal hydroxides such as sodium hydroxide, potassium hydroxide, rubidium hydroxide, and cesium hydroxide. These pH adjusting agents may be used alone or two or more thereof may be used in combination.

Examples of inorganic acids and salts thereof include phosphoric acid, phosphonic acid, sulfuric acid, hydrochloric acid, nitric acid, and salts thereof. Among these, phosphoric acid, phosphonic acid, nitric acid, and salts thereof are preferable, and phosphoric acid, phosphonic acid, and salts thereof are more preferable.

1.1.6. pH

The pH of the semiconductor processing composition according to the first embodiment is preferably 1 or more and 6 or less and more preferably 2 or more and 5.5 or less. Cobalt tends to easily form a soft surface under an acidic environment. Therefore, for example, when the semiconductor processing composition is used as a CMP slurry, when the pH is within the above range, this is preferable because it is possible to improve a polishing rate of the cobalt site. In addition, for example, when the semiconductor processing composition is used as a cleaning agent, when the pH is within the above range, this is preferable because it is possible to effectively remove residues on the exposed cobalt surface to be treated.

The pH of the semiconductor processing composition according to the first embodiment can be adjusted by appropriately increasing or decreasing the amount of each of the above components added.

1.1.7. Mass Ratio

In the semiconductor processing composition according to the first embodiment, when the content of the glutamic acid is Ma1 [mass %], and the content of at least one selected from the group consisting of histidine, cysteine, and glycine is Mat [mass %], the lower limit value of the mass ratio Ma1/Ma2 is preferably 0.1, more preferably 0.2, and particularly preferably 0.3. The upper limit value of the mass ratio Ma1/Ma2 is preferably 20, more preferably 10, and particularly preferably 5. When the value of the mass ratio Ma1/Ma2 is within the above range, a protective film for minimizing corrosion can be more effectively formed on the exposed cobalt surface.

In the semiconductor processing composition according to the first embodiment, when the content of the glutamic acid is Ma1 [mass %], and the content of at least one selected from the group consisting of ammonia and an ammonium salt is Ma3 [mass %], the lower limit value of the mass ratio Ma1/Ma3 is preferably 0.1, more preferably 0.5, and particularly preferably 1. The upper limit value of the mass ratio Ma1/Ma3 is preferably 15, more preferably 13, and particularly preferably 10. When the value of the mass ratio Ma1/Ma3 is within the above range, a protective film derived from glutamic acid for minimizing corrosion on the exposed cobalt surface can be more effectively formed.

In the semiconductor processing composition according to the first embodiment, when the content of at least one selected from the group consisting of histidine, cysteine, and glycine is set as Ma2 [mass %], and the content of at least one selected from the group consisting of ammonia and an ammonium salt is set as Ma3 [mass %], the lower limit value of the mass ratio Ma2/Ma3 is preferably 0.1, more preferably 0.5, and particularly preferably 1. The upper limit value of the mass ratio Ma2/Ma3 is preferably 15, more preferably 13, and particularly preferably 10. When the value of the mass ratio Ma2/Ma3 is within the above range, a protective film of a water-insoluble complex derived from at least one selected from the group consisting of histidine, cysteine, and glycine for minimizing corrosion on the exposed cobalt surface can be more effectively formed.

1.1.8. Method of Preparing Semiconductor Processing Composition

The semiconductor processing composition according to the first embodiment can be prepared by dissolving or dispersing glutamic acid, and at least one selected from the group consisting of histidine, cysteine and glycine in a liquid medium, and additionally adding other components as necessary. The order of mixing in and the method of mixing the above components are not particularly limited.

In addition, the semiconductor processing composition according to the first embodiment that is prepared as a concentrated type stock solution and diluted in a liquid medium such as water during use can be used.

### 1.2. Second Embodiment

The semiconductor processing composition according to the second embodiment of the disclosure is a semiconductor processing composition for processing an exposed cobalt surface, and includes a compound having a structure in which glutamic acid, and at least one selected from the group consisting of histidine, cysteine and glycine are peptide-bonded. The semiconductor processing composition according to the second embodiment differs from the semiconductor processing composition according to the first embodiment in that it includes a “compound having a structure in which glutamic acid, and at least one selected from the group consisting of histidine, cysteine and glycine are peptide-bonded” in place of “glutamic acid,” and “at least one selected from the group consisting of histidine, cysteine, and glycine.” Hereinafter, the semiconductor processing composition according to the second embodiment will be described.

1.2.1. Compound Having a Peptide-Bonded Structure.

The semiconductor processing composition according to the second embodiment includes a compound having a structure in which glutamic acid, and at least one selected from the group consisting of histidine, cysteine and glycine are peptide-bonded (hereinafter referred to as a “peptide component”). The peptide component has a function of minimizing corrosion of a cobalt site.

The peptide component may have a structure in which glutamic acid, and at least one selected from the group consisting of histidine, cysteine and glycine are peptide-bonded, and regarding other structures, additionally, the peptide component may have a structure in which amino acids other than glutamic acid, histidine, cysteine and glycine are peptide-bonded. Regarding amino acids other than glutamic acid, histidine, cysteine, and glycine, for example natural amino acids such as alanine, arginine, and asparagine are preferable. Specific examples of a peptide component having such a structure in which two or more peptide bonds are formed include glutathione. Glutathione is a tripeptide in which glutamic acid, cysteine and glycine are peptide-bonded.

When the semiconductor processing composition according to the second embodiment is used as a processing agent such as a cleaning agent or a CMP slurry, the lower limit value of the content of the peptide component is preferably 0.001 mass %, and more preferably 0.005 mass % with respect to the total mass of the processing agent. The upper limit value of the content of the peptide component is preferably 1 mass %, and more preferably 0.1 mass %.

1.2.2. Components Other than Peptide Component

Like the semiconductor processing composition according to the first embodiment, the semiconductor processing composition according to the second embodiment may contain additives such as ammonia and an ammonium salt, an oxidant, an abrasive, a surfactant, and a pH adjusting agent in addition to a liquid medium. The semiconductor processing composition according to the second embodiment can contain these additives for the same purposes and in the same contents as the semiconductor processing composition according to the first embodiment.

1.2.3. pH

The pH of the semiconductor processing composition according to the second embodiment is preferably 1 or more and 6 or less, and more preferably 2 or more and 5.5 or less. Cobalt tends to easily form a soft surface under an acidic environment. Therefore, for example, when the semiconductor processing composition is used as a CMP slurry, when the pH is within the above range, this is preferable because it is possible to improve a polishing rate of the cobalt site. In addition, for example, when the semiconductor processing composition is used as a cleaning agent, when the pH is within the above range, this is preferable because it is possible to effectively remove residues on the exposed cobalt surface to be treated.

The pH of the semiconductor processing composition according to the second embodiment can be adjusted by appropriately increasing or decreasing the amount of each of the above components added.

1.2.4. Method of Preparing Semiconductor Processing Composition

The semiconductor processing composition according to the second embodiment can be prepared by dissolving or dispersing a peptide component in a liquid medium and additionally adding other components as necessary. The order of mixing in and the method of mixing the above components are not particularly limited.

In addition, the semiconductor processing composition according to the second embodiment that is prepared as a concentrated type stock solution and diluted in a liquid medium such as water during use can be used.

### 2. PROCESSING METHOD

A processing method according to one embodiment of the disclosure includes a process of processing a surface of a workpiece having an exposed cobalt surface using the above semiconductor processing composition in a condition in which the temperature of the composition is 20 to 40° C. When the above semiconductor processing composition is used, it is possible to reduce an etching rate of cobalt and minimize corrosion of the cobalt site. Therefore, the processing method according to the present embodiment is particularly beneficial for processing a workpiece having an exposed cobalt surface.

The processing method is not particularly limited, and when the above semiconductor processing composition is used as a cleaning agent for cleaning a semiconductor surface, a method of bringing the above semiconductor processing composition into direct contact with a workpiece having an exposed cobalt surface (for example, a wiring board) is performed. Examples of a method of bringing a semiconductor processing composition into direct contact with a workpiece include a dip type method in which a workpiece is immersed in a cleaning tank filled with a semiconductor processing composition; a spin type method in which the workpiece is rotated at a high speed while the semiconductor processing composition is caused to flow on the workpiece through a nozzle; and a spray type method in which a semiconductor processing composition is sprayed onto the workpiece to perform cleaning. In addition, examples of a device that performs such a method include a batch type cleaning device that cleans a plurality of workpieces stored in a cassette at the same time and a single-wafer type cleaning device that attaches one workpiece to a holder and cleans it.

In the processing method according to the present embodiment, the temperature of the semiconductor processing composition is generally 20 to 40° C. When the temperature is within this range, it is possible to suitably process a surface of a workpiece without degrading components contained in the semiconductor processing composition.

In the processing method according to the present embodiment, a time for which the semiconductor processing composition and the exposed cobalt surface of the workpiece are in contact with other is preferably 30 to 60 seconds. When the time is within this range, it is possible to sufficiently remove contaminants from the surface of the workpiece and reduce etching and corrosion of the cobalt site.

In addition, for the above semiconductor processing composition, in addition to a method of bringing into direct contact with a workpiece, a cleaning method using a physical force is preferably used in combination. Therefore, it is possible to improve removability of contaminants caused by particles attached to the workpiece and shorten a cleaning time. Examples of a cleaning method using a physical force include scrub cleaning using a cleaning brush and ultrasonic cleaning.

In addition, before and after processing using the processing method according to the present embodiment, cleaning with ultrapure water or an alcohol solvent such as isopropanol may be performed.

### 3. EXAMPLES

While the disclosure will be described below with reference to examples, the disclosure is not limited to these examples. Here, in the examples, “parts” and “%” are based on mass unless otherwise specified.

### 3.1. Example 1

### 3.1.1. Preparation of Semiconductor Processing Composition

0.025 mass % of glutamic acid, 0.025 mass % of histidine, 0.005 mass % of an ammonia 29% aqueous solution (commercially available from Mitsubishi Gas Chemical Company, Inc.) in terms of NH₃, 0.5 mass % of a hydrogen peroxide 35% aqueous solution (commercially available from FUJIFILM Wako Pure Chemical Corporation) in terms of H₂O₂ as an oxidant, and a nitric acid 61% aqueous solution (commercially available from Kanto Chemical Co., Inc.) as a pH adjusting agent so that the pH was shown in the following Table 1 were put into a polyethylene container, deionized water was put into as the remaining liquid medium and mixing was performed so that the total amount was 100 mass % and stirring was then performed for 15 minutes to prepare a semiconductor processing composition of Example 1.

### 3.1.2. Evaluation of Etching Rate (ER)

A 12-inch silicon wafer on which cobalt (Co) was deposited on a surface by a sputtering method (a silicon substrate with a 12-inch thermal oxide film on which a cobalt film with a film thickness of 2000 Å was laminated) was cut into 1 cm×3 cm to prepare a test piece. A film thickness of this test piece was measured in advance using MODEL Σ-5 (commercially available from NPS, Inc.). Next, 30 mL of the semiconductor processing composition of Example 1 was put into the polyethylene container, and kept at 25° C., and the test piece having a film of cobalt was immersed in the semiconductor processing composition for 15 minutes. Then, cleaning was performed with running water for 10 seconds and drying was performed. The film thickness of the test piece after the immersion treatment was measured again, and the amount of the film thickness reduced was divided by an immersion time of 15 minutes to calculate an etching rate (ER, unit: Å/min.). The results are shown in Table 1. A lower etching rate was determined as being better, and when the etching rate was 30 Å/min or less, it was determined as being favorable because it was able to be practically used.

### 3.1.3. Evaluation of Corrosion

A 12-inch silicon wafer on which cobalt (Co) was deposited on a surface by a sputtering method (a silicon substrate with a 12-inch thermal oxide film on which a cobalt film with a film thickness of 2000 Å was laminated) was maintained at the processing temperature described in Table 1, and immersed in the semiconductor processing composition of Example 1 for a time described in Table 1 and then cleaned with running water for 10 seconds and dried. Then, the number of corroded parts on the surface was counted using a defect inspection device (model “KLA2351” commercially available from KLA-Tencor). Evaluation criteria were as follows. The evaluation results are shown in Table 1.

### (Evaluation Criteria)

A: When the number of corroded parts was 1.5 parts/cm² or less, it was determined that it was able to be practically used and determined to be good.

B: When the number of corroded parts was 1.5 parts/cm² or more, it was determined that it was not able to be practically used and determined to be defective.

### 3.2. Examples 2 to 9, 11 to 26, and Comparative Examples 1 to 4

Semiconductor processing compositions were prepared and evaluated in the same manner as in Example 1 except that the composition and content were changed to those described in Table 1 to Table 4. The results are shown in Table 1 to Table 4.

### 3.3. Examples 27 to 29

Semiconductor processing compositions were prepared and evaluated in the same manner as in Example 1 except that the peptide component described in Table 3 was added in place of glutamic acid and histidine. The results are shown in Table 3.

### 3.4. Example 10 and Comparative Example 5

Semiconductor processing compositions were prepared and evaluated in the same manner as in Example 1 except that the composition and content were changed to those described in Table 1 or Table 4, and a phosphoric acid 85% aqueous solution (commercially available from Rasa Industries, Ltd.) was used as a pH adjusting agent in place of nitric acid. The results are shown in Table 1 or Table 4.

### 3.5. Evaluation Results

Table 1 to Table 4 show the compositions of the semiconductor processing compositions used in examples and comparative examples and evaluation results.

TABLE 1

| | | | Example 1 | Example 2 | Example 3 | Example 4 | Example 5 | Example 6 |
|---|---|---|---|---|---|---|---|---|
| | Glutamic | Ma1(mass %) | 0.025 | 0.045 | 0.0475 | 0.005 | 0.025 | 0.033 |
| | acid | | | | | | | |
| Semi- | Histidine | (mass %) | 0.025 | 0.005 | 0.0025 | 0.045 | | |
| conductor | Cysteine | (mass %) | | | | | 0.025 | 0.017 |
| processing | Glycine | (mass %) | | | | | | |
| composition | Ma2(mass %) | | 0.025 | 0.005 | 0.0025 | 0.045 | 0.025 | 0.017 |
| | Peptide | (mass %) | | | | | | |
| | component | | | | | | | |
| | Ammonia | Ma3(mass %) | 0.005 | 0.005 | 0.005 | 0.005 | 0.005 | 0.005 |
| | Ma1/Ma2 | | 1.0 | 9.0 | 19.0 | 0.1 | 1.0 | 1.9 |
| | Ma1/Ma3 | | 5.0 | 9.0 | 9.5 | 1.0 | 5.0 | 6.6 |
| | Ma2/Ma3 | | 5.0 | 1.0 | 0.5 | 9.0 | 5.0 | 3.4 |
| | pH | | 3.5 | 3.0 | 3.0 | 4.2 | 3.0 | 3.2 |
| Evaluation | Etching rate | (Å/min.) | 8.4 | 2.7 | 2.0 | 30 | 20 | 15 |
| result | evaluation | | | | | | | |
| | Corrosion | Processing | 25 | 35 | 40 | 20 | 25 | 30 |
| | evaluation | temperature(° C.) | | | | | | |
| | | Processing time | 60 | 30 | 60 | 30 | 30 | 60 |
| | | (seconds) | | | | | | |
| | | Evaluation result | A | A | A | A | A | A |

| | | | Example 7 | Example 8 | Example 9 | Example 10 |
|---|---|---|---|---|---|---|
| | Glutamic | Ma1(mass %) | 0.017 | 0.01 | 0.025 | 0.025 |
| | acid | | | | | |
| Semi- | Histidine | (mass %) | | | 0.025 | 0.025 |
| conductor | Cysteine | (mass %) | 0.033 | 0.04 | | |
| processing | Glycine | (mass %) | | | | |
| composition | Ma2(mass %) | | 0.033 | 0.04 | 0.025 | 0.025 |
| | Peptide | (mass %) | | | | |
| | component | | | | | |
| | Ammonia | Ma3(mass %) | 0.005 | 0.005 | | 0.002 |
| | Ma1/Ma2 | | 0.5 | 0.3 | 1.0 | 1.0 |
| | Ma1/Ma3 | | 3.4 | 2.0 | | 12.5 |
| | Ma2/Ma3 | | 6.6 | 8.0 | | 12.5 |
| | pH | | 3.2 | 3.2 | 3.0 | 3.0 |
| Evaluation | Etching rate | (Å/min.) | 25 | 28 | 22 | 21 |
| result | evaluation | | | | | |
| | Corrosion | Processing | 25 | 25 | 35 | 25 |
| | evaluation | temperature(° C.) | | | | |
| | | Processing time | 30 | 40 | 30 | 50 |
| | | (seconds) | | | | |
| | | Evaluation result | A | A | A | A |

TABLE 2

| | | | Example 11 | Example 12 | Example 13 | Example 14 | Example 15 | Example 16 |
|---|---|---|---|---|---|---|---|---|
| | Glutamic | Ma1(mass %) | 0.025 | 0.017 | 0.041 | 0.025 | 0.0083 | 0.0125 |
| | acid | | | | | | | |
| Semi- | Histidine | (mass %) | 0.025 | 0.017 | 0.0045 | 0.0125 | 0.0334 | 0.025 |
| conductor | Cysteine | (mass %) | | 0.017 | 0.0045 | 0.0125 | 0.0083 | 0.0125 |
| processing | Glycine | (mass %) | | | | | | |
| composition | Ma2(mass %) | | 0.025 | 0.034 | 0.009 | 0.025 | 0.0417 | 0.0375 |
| | Peptide | (mass %) | | | | | | |
| | component | | | | | | | |
| | Ammonia | Ma3(mass %) | 0.005 | 0.005 | 0.005 | 0.005 | 0.005 | 0.005 |
| | Ma1/Ma2 | | 1.0 | 0.5 | 4.6 | 1.0 | 0.2 | 0.3 |
| | Ma1/Ma3 | | 5.0 | 3.4 | 8.2 | 5.0 | 1.7 | 2.5 |
| | Ma2/Ma3 | | 5.0 | 6.8 | 1.8 | 5.0 | 8.3 | 7.5 |
| | pH | | 5.3 | 3.2 | 2.7 | 2.9 | 3.6 | 3.5 |
| Evaluation | Etching rate | (Å/min.) | 6.2 | 9.3 | 3.3 | 7.1 | 29 | 26 |
| result | evaluation | | | | | | | |
| | Corrosion | Processing | 40 | 25 | 40 | 25 | 25 | 25 |
| | evaluation | temperature(° C.) | | | | | | |
| | | Processing time | 30 | 60 | 40 | 60 | 30 | 30 |
| | | (seconds) | | | | | | |
| | | Evaluation result | A | A | A | A | A | A |

| | | | Example 17 | Example 18 | Example 19 | Example 20 |
|---|---|---|---|---|---|---|
| | Glutamic | Ma1(mass %) | 0.0083 | 0.0125 | 0.017 | 0.041 |
| | acid | | | | | |
| Semi- | Histidine | (mass %) | 0.0083 | 0.0125 | 0.017 | 0.0045 |
| conductor | Cysteine | (mass %) | 0.0334 | 0.025 | | |
| processing | Glycine | (mass %) | | | 0.017 | 0.0045 |
| composition | Ma2(mass %) | | 0.0417 | 0.0375 | 0.034 | 0.009 |
| | Peptide | (mass %) | | | | |
| | component | | | | | |
| | Ammonia | Ma3(mass %) | 0.005 | 0.005 | 0.005 | 0.005 |
| | Ma1/Ma2 | | 0.2 | 0.3 | 0.5 | 4.6 |
| | Ma1/Ma3 | | 1.7 | 2.5 | 3.4 | 8.2 |
| | Ma2/Ma3 | | 8.3 | 7.5 | 6.8 | 1.8 |
| | pH | | 3.3 | 3.2 | 3.2 | 3.0 |
| Evaluation | Etching rate | (Å/min.) | 28 | 27 | 7.5 | 2.7 |
| result | evaluation | | | | | |
| | Corrosion | Processing | 25 | 25 | 40 | 40 |
| | evaluation | temperature(° C.) | | | | |
| | | Processing time | 30 | 30 | 30 | 50 |
| | | (seconds) | | | | |
| | | Evaluation result | A | A | A | A |

TABLE 3

| | | | Example 21 | Example 22 | Example 23 | Example 24 | Example 25 |
|---|---|---|---|---|---|---|---|
| | Glutamic | Ma1(mass %) | 0.0334 | 0.025 | 0.0083 | 0.0125 | 0.0083 |
| | acid | | | | | | |
| Semi- | Histidine | (mass %) | 0.0083 | 0.0125 | 0.0334 | 0.025 | 0.0083 |
| conductor | Cysteine | (mass %) | | | | | |
| processing | Glycine | (mass %) | 0.0083 | 0.0125 | 0.0083 | 0.0125 | 0.0334 |
| composition | Ma2(mass %) | | 0.0166 | 0.025 | 0.0417 | 0.0375 | 0.0417 |
| | Peptide | (mass %) | | | | | |
| | component | | | | | | |
| | Ammonia | Ma3(mass %) | 0.005 | 0.005 | 0.005 | 0.005 | 0.005 |
| | Ma1/Ma2 | | 2.0 | 1.0 | 0.2 | 0.3 | 0.2 |
| | Ma1/Ma3 | | 6.7 | 5.0 | 1.7 | 2.5 | 1.7 |
| | Ma2/Ma3 | | 3.3 | 5.0 | 8.3 | 7.5 | 8.3 |
| | pH | | 3.0 | 3.0 | 3.6 | 3.5 | 3.2 |
| Evaluation | Etching rate | (Å/min.) | 4.1 | 5.7 | 29 | 14 | 29 |
| result | evaluation | | | | | | |
| | Corrosion | Processing | 35 | 30 | 25 | 40 | 25 |
| | evaluation | temperature(° C.) | | | | | |
| | | Processing time | 60 | 40 | 30 | 30 | 30 |
| | | (seconds) | | | | | |
| | | Evaluation result | A | A | A | A | A |

| | | | Example 26 | Example 27 | Example 28 | Example 29 |
|---|---|---|---|---|---|---|
| | Glutamic | Ma1(mass %) | 0.0125 | | | |
| | acid | | | | | |
| Semi- | Histidine | (mass %) | 0.0125 | | | |
| conductor | Cysteine | (mass %) | | | | |
| processing | Glycine | (mass %) | 0.025 | | | |
| composition | Ma2(mass %) | | 0.0375 | | | |
| | Peptide | (mass %) | | 0.05 | 0.05 | 0.05 |
| | component | | | | | |
| | Ammonia | Ma3(mass %) | 0.005 | 0.005 | 0.005 | 0.005 |
| | Ma1/Ma2 | | 0.3 | | | |
| | Ma1/Ma3 | | 2.5 | | | |
| | Ma2/Ma3 | | 7.5 | | | |
| | pH | | 3.1 | 2.7 | 2.7 | 2.7 |
| Evaluation | Etching rate | (Å/min.) | 25 | 19 | 19 | 19 |
| result | evaluation | | | | | |
| | Corrosion | Processing | 25 | 25 | 25 | 40 |
| | evaluation | temperature(° C.) | | | | |
| | | Processing time | 30 | 60 | 40 | 30 |
| | | (seconds) | | | | |
| | | Evaluation result | A | A | A | A |

TABLE 4

| | | | Comparative | Comparative | Comparative | Comparative | Comparative |
|---|---|---|---|---|---|---|---|
| | | | Example 1 | Example 2 | Example 3 | Example 4 | Example 5 |
| | Glutamic | Ma1(mass %) | | | | | |
| | acid | | | | | | |
| Semi- | Histidine | (mass %) | | | 0.05 | | |
| conductor | Cysteine | (mass %) | | | | 0.05 | |
| processing | Glycine | (mass %) | | | | | |
| composition | Ma2(mass %) | | | | 0.05 | 0.05 | |
| | Peptide | (mass %) | | | | | |
| | component | | | | | | |
| | Ammonia | Ma3(mass %) | 0.005 | | 0.005 | 0.005 | 0.005 |
| | Other | Type | | KOH | | | |
| | additives | (mass %) | | 0.01 | | | |
| | Ma1/Ma2 | | | | 0.0 | 0.0 | |
| | Ma1/Ma3 | | | | 0.0 | 0.0 | |
| | Ma2/Ma3 | | | | 10.0 | 10.0 | |
| | pH | | 2.4 | 2.6 | 5.6 | 2.7 | 2.6 |
| Evaluation | Etching rate | (Å/min.) | 100 | 130 | 59 | 93 | 108 |
| result | evaluation | | | | | | |
| | Corrosion | Processing | 25 | 15 | 25 | 25 | 45 |
| | evaluation | temperature(° C.) | | | | | |
| | | Processing time | 10 | 60 | 70 | 30 | 10 |
| | | (seconds) | | | | | |
| | | Evaluation result | B | B | B | B | B |

Descriptions of the components described in Table 1 to Table 4 are supplemented below.

Glutamic acid: product name “L-glutamic acid” commercially available from Nippon Rika Co., Ltd.

Histidine: product name “L-histidine” commercially available from Nippon Rika Co., Ltd.

Cysteine: product name “L-cysteine” commercially available from Nippon Rika Co., Ltd.

Glycine: product name “glycine” commercially available from Fuso Chemical Co., Ltd.

Peptide component: product name “glutathione (reduced type),” commercially available from Kyowa Hakko Bio Co., Ltd., tripeptide in which glutamic acid, cysteine, and glycine were peptide-bonded

KOH: product name “48% potassium hydroxide” commercially available from Kanto Chemical Co., Inc.

It can be clearly understood from Table 1 to Table 4 that, when the semiconductor processing compositions according to the disclosure were used, in any case, it was possible to reduce an etching rate of the cobalt film and minimize corrosion of the cobalt site.

The disclosure is not limited to above embodiments, and various modifications can be made. For example the disclosure includes a configuration substantially the same configuration (for example, a configuration having the same function, method and result, or a configuration having the same object and effect) as the configuration described in the embodiment. In addition, the disclosure includes a configuration in which components that are not essential in the configuration described in the embodiment are replaced. In addition, the disclosure includes a configuration having the same operations and effects as the configuration described in the embodiment and a configuration that can achieve the same object. In addition, the disclosure includes a configuration obtained by adding known techniques to the configuration described in the embodiment.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor processing composition for processing an exposed cobalt surface, comprising
glutamic acid; and
at least one selected from the group consisting of histidine, cysteine, and glycine.

2. The semiconductor processing composition according to claim 1,
wherein, when the content of the glutamic acid is Ma1 mass %, and the content of the at least one selected from the group consisting of histidine, cysteine, and glycine is Ma2 mass %, Ma1/Ma2=0.1 to 20.

3. A semiconductor processing composition for processing an exposed cobalt surface comprising a compound having a structure in which glutamic acid, and at least one selected from the group consisting of histidine, cysteine and glycine are peptide-bonded.

4. The semiconductor processing composition according to claim 1, further comprising
at least one selected from the group consisting of ammonia and an ammonium salt.

5. The semiconductor processing composition according to claim 1,
wherein the pH is 1 to 6.

6. The semiconductor processing composition according to claim 1, further comprising
an oxidant.

7. A processing method, comprising
a process of processing a surface of a workpiece having an exposed cobalt surface using the semiconductor processing composition according to claim 1 in a condition in which the temperature of the composition is 20 to 40° C.

8. The processing method according to claim 7,
wherein, in the process, the composition and the exposed cobalt surface are brought into contact with each other for 30 to 60 seconds.

9. The semiconductor processing composition according to claim 3, further comprising
at least one selected from the group consisting of ammonia and an ammonium salt.

10. The semiconductor processing composition according to claim 3,
wherein the pH is 1 to 6.

11. The semiconductor processing composition according to claim 3, further comprising
an oxidant.

12. A processing method, comprising
a process of processing a surface of a workpiece having an exposed cobalt surface using the semiconductor processing composition according to claim 3 in a condition in which the temperature of the composition is 20 to 40° C.

13. The processing method according to claim 12,
wherein, in the process, the composition and the exposed cobalt surface are brought into contact with each other for 30 to 60 seconds.
